(19) United States
(12) Patent Application Publication
(10) Pub. No.: US 2024/0263339 A1
(43) Pub. Date: Aug. 8, 2024

(54) Method for Manufacturing a Component by Means of Layered Construction

(71) Applicant: Friedrich-Alexander-Universität Erlangen-Nürnberg, Erlangen (DE)

(72) Inventors: Carolin Körner, Feucht (DE); Julian Pistor, Kulmbach (DE)

(73) Assignee: Friedrich-Alexander-Universität Erlangen-Nürnberg, Erlangen (DE)

(21) Appl. No.: 18/567,198

(22) PCT Filed: Jun. 2, 2022
(86) PCT No.: PCT/EP2022/065009

§ 371 Date: Dec. 5, 2023

(30) Foreign Application Priority Data
Jun. 7, 2021 (DE) 10 2021 114 560.0

(51) Int. Cl. C30B 13/06; B22F 10/28; B23K 26/342; B23K 103/12; B23K 103/18; B23P 6/00; B33Y 10/00; B33Y 80/00; C30B 13/22; C30B 13/24; C30B 29/52

(52) U.S. Cl. CPC C30B 13/06; B22F 10/28; B23K 26/342; B23P 6/007; B33Y 10/00; B33Y 80/00; C30B 13/22; C30B 13/24; C30B 29/52; B22F 2998/10; B23K 2103/12; B23K 2103/26

(57) ABSTRACT

The invention relates to a method for producing a component by means of layered construction, by combining a plurality of crystallites of a metallic material to form a single crystal. The single crystal is formed by thermomechanically activated successive anisotropic plastic deformation. The metallic material is heated during the construction of a new layer, with the result that the metallic material is melted in a linear region. The linear region is moved in order to construct the new layer.

The invention relates to a method for producing a component by means of layered construction. The component comprises at least one single crystal.

The conventional production of single crystals is normally based on epitaxial crystal growth starting from a seed crystal. Controlled single crystal growth can then be effected either according to the Czochralski method by crucible pulling, by zone melting, or according to the Bridgman method by directional solidification. The crystal orientation of the seed crystal determines the crystal orientation of the resulting single crystal.

European patent specification EP 1 495 166 B1 relates to a method for producing monocrystalline metallic layers on a monocrystalline substrate by means of layered construction by epitaxial growth starting from a, for example pulverulent, material. The substrate is in particular a workpiece to be repaired or reconditioned.

European patent application EP 3 459 654 A1 also relates to a method for producing monocrystalline metallic layers on a monocrystalline substrate while maintaining the monocrystalline microstructure.

The Bridgman method, known for example from German patent application DE 10 2014 113 806 A1, is used to produce monocrystalline turbine blades from a nickel-based alloy. A single crystal is realized by selecting one grain. For this, crystals the crystal orientation of which almost coincides with the solidification direction are selected from a very large number of seed crystals by directional solidification by grain selection. The solidification direction corresponds to the <001> direction of the crystals in the case of cubic crystal systems. After this first selection over a length of a few centimeters, a further, geometric selection is effected with the aid of a spiral selector. The secondary crystal orientation of the single crystals is fixed randomly by the spiral selector.

A disadvantage of this method is that with it a more precise crystal orientation cannot be adjusted. The crystal orientation in the solidification direction can deviate a few degrees from the desired crystal orientation. The secondary crystal orientation cannot be influenced at all.

The object of the present invention is to eliminate the disadvantages from the state of the art. In particular, a method is to be specified with which the crystal orientation of single crystals can be optimized. In particular, the quality in the production of single crystals is to be improved thereby. Furthermore, a component with a single crystal with a controlled crystal orientation is to be provided and a method for the production thereof is to be specified.

According to the invention, this object is achieved by a method according to the subject-matter of claim 1 and by a component according to the subject-matter of claim 20. Advantageous embodiments of the invention are specified for this in each case in the dependent claims.

In accordance with the invention, a component is produced by means of layered construction by combining a plurality of crystallites of a metallic material to form a single crystal. The single crystal is formed by thermomechanically activated successive anisotropic plastic deformation. The metallic material is heated during the construction of a new layer, with the result that the metallic material is melted in a linear region. The linear region is moved in order to construct the new layer.

By the term “thermomechanically activated successive anisotropic plastic deformation” is meant a plastic deformation of the metallic material which is caused by mechanical stresses occurring during heating, in particular melting, and subsequent cooling, in particular solidification, of the metallic material. During heating, in particular melting, and subsequent cooling, in particular solidification, thermal expansions can occur, which cause the mechanical stresses. The mechanical stresses are generated in a targeted manner, preferably by adjustment of the extension direction, speed and/or temperature of the melted linear region and/or its surroundings. The mechanical stresses preferably exceed the yield point of the metallic material. The mechanical stresses preferably have a preferred direction because of the linear design of the melted linear region. An anisotropic mechanical stress field is thus generated. An anisotropic plastic deformation thereby results. This anisotropy preferably leads to the generation of a single crystal. The metallic material is gradually, i.e. successively, subjected to the plastic deformation. The component is constructed layer by layer in a construction direction. The individual layers are also preferably constructed gradually by being traversed by the melted linear region. The crystal orientation, in particular the primary (in the construction direction) and secondary (in the layer plane) crystal orientation, can be precisely adjusted preferably by the thermomechanical stress field generated in a targeted manner by adjustment of extension direction, speed and/or temperature of the melted linear region.

The mechanical stresses can be compressive stresses or tensile stresses.

The mechanical stresses preferably occur in the metallic material of a new layer and in the metallic material already solidified beforehand in the course of the layer-by-layer construction, in particular in the region of up to 5 mm underneath the new layer. The already solidified material, located directly underneath the new layer, in particular up to 5 mm underneath it, preferably also has mechanical stresses.

The component is preferably subjected to a mechanical clamping in the course of a material-bonding connection created by melt metallurgy. Mechanical stresses are thereby not relieved by displacement of the already grown single crystal, and a self-clamping is referred to in this connection. The mechanical stresses are caused in particular by the interaction of thermal expansion and self-clamping.

The component is preferably constructed gradually on a base plate. The base plate can be formed of the same metallic material as the component. Alternatively, the base plate can be formed of another metallic material.

The component is preferably constructed with a crystal structure that differs from the base plate. The component thus preferably differs from the base plate in terms of its crystal structure.

The component can be separated from the base plate after it has been completed. A starting region of the component, in which a monocrystalline state has not yet been set, is preferably additionally detached.

Alternatively, the component can be constructed gradually starting from a powder bed. In this embodiment as well, after the component has been completed, a starting region of the component, in which a monocrystalline state has not yet been set, is preferably detached.

In a departure from the state of the art, the component is thus preferably not produced starting from a monocrystalline substrate. The component is preferably constructed on a polycrystalline base plate or on a powder bed.

The component is preferably separated from the base plate and/or from a starting region of the component, in which a monocrystalline state has not yet been set, after it has been completed. Furthermore, the component can be constructed so weakly connected to the base plate that the component can be easily removed from the base plate. For this, the component can for example be sintered onto the base plate.

Within the meaning of the present application, the term “linear region” refers to the melted linear region according to the claims. Repeating the term “melted” is usually avoided. The linear region has an extension direction. Because of the self-clamping, much greater mechanical stresses preferably form in this extension direction than perpendicular thereto in the plane of the new layer. The linear region is preferably moved perpendicular to its extension direction. Correspondingly, because of the self-clamping, much greater mechanical stresses form in the extension direction of the linear region than in the movement direction of the linear region.

The mechanical stress field is therefore anisotropic. This anisotropy leads to the anisotropic plastic deformation and to the generation of a single crystal. The crystal orientation, in particular the primary and secondary crystal orientation, can therefore preferably be adjusted precisely by adjustment of the extension direction of the linear region and the thus generated mechanical stress field.

In the case of the crystal orientation, in the context of this patent application, a distinction is drawn between the primary and the secondary crystal orientation. To explain the primary and the secondary crystal orientation, an installation space with an xy plane as construction plane and a z direction as construction direction is assumed. The primary crystal orientation indicates the alignment of the single crystal or an axis of the single crystal with respect to the z direction. The single crystal is preferably aligned in the z direction, but can also be tilted with respect to the z direction. The secondary crystal orientation represents a specific rotational position of the crystal lattice about the axis of the single crystal. In the case of an alignment of the single crystal in the z direction, the secondary crystal orientation denotes the specific rotational position of the crystal lattice about the z axis or, in other words, the location of the crystal lattice in the xy plane.

The linear region is preferably surrounded by a heat-affected zone. The metallic material is preferably not melted in the heat-affected zone. More precisely, in the heat-affected zone the metallic material is preferably in part not yet melted, in part no longer melted. The heat-affected zone is preferably moved together with the linear region in order to construct the new layer. There are preferably high temperature gradients in the heat-affected zone. Particularly great thermally induced mechanical stresses thereby result in the heat-affected zone. The mechanical stresses preferably exceed the yield point in the heat-affected zone. A plastic deformation of the metallic material therefore preferably results in the heat-affected zone. The shape of the heat-affected zone preferably substantially corresponds to the shape of the linear region. The mechanical stresses in the heat-affected zone therefore also have a preferred direction. The plastic deformation in the heat-affected zone is thus also anisotropic. The heat-affected zone thus preferably contributes to the generation of a single crystal precisely adjusted in terms of its crystal orientation, preferably in terms of its primary and secondary crystal orientation.

A temperature field is preferably generated in the installation space. A heat input can be effected directly into the linear region, into the heat-affected zone, into the new layer, into the layer produced directly before the new layer and/or into the layers produced directly before the new layer. Alternatively or additionally, a heat input onto the entire installation space can be effected in particular from outside.

During the construction of the new layer the metallic material can be heated to a first temperature and/or a first temperature range directly in the linear region. By this is meant that a heat input is effected directly into the linear region.

The metallic material in the heat-affected zone is preferably heated to a second temperature and/or a second temperature range. The first temperature or the first temperature range is preferably higher than the second temperature or the second temperature range.

During the construction of the new layer, the metallic material is preferably heated at least to a third temperature and/or a third temperature range in the entire new layer. The third temperature is also called construction temperature. The second temperature or the second temperature range is preferably higher than the third temperature or the third temperature range.

In order to heat the metallic material in the entire new layer, a heat input can also be effected directly onto the new layer outside the linear region. The heat input per unit area being effected directly into the linear region is preferably greater than the heat input per unit area being effected directly onto the new layer outside the linear region.

A depth of the linear region can be limited to the new layer. The linear region preferably reaches through the new layer and penetrates into the layer produced directly before the new layer and/or into the layers produced directly before the new layer. The depth of the linear region preferably extends over the new layer and onto one to ten, particularly preferably onto five to ten, layers produced directly before the new layer. The metallic material is thereby preferably subjected to a melting and solidification several times.

In the heat-affected zone, the temperature field also acts on already solidified metallic material in the layer produced directly before the new layer and/or in the layers produced directly before the new layer. These layers are also mechanically distorted. This means that the mechanical stress field also extends onto the layer produced directly before the new layer or onto the layers produced directly before the new layer. The generation of the single crystal can be promoted by this already present anisotropic stress field.

The mechanical stresses can exceed the yield point in particular in the linear region, in the heat-affected zone, in the new layer, in the layer produced directly before the new layer and/or in the layers produced directly before the new layer. In the linear region, in the heat-affected zone, in the new layer, in the layer produced directly before the new layer and/or in the layers produced directly before the new layer, plastic deformations can therefore result, which preferably contribute to the generation of a single crystal precisely adjusted in terms of its crystal orientation, preferably in terms of its primary and secondary crystal orientation, because of the anisotropy of the mechanical stresses.

The metallic material in the linear region can be melted with one or more time interruptions during the construction of the new layer. The metallic material in the linear region is preferably melted continually during the construction of the new layer.

The crystallites preferably have a size in a range of from 5 μm to 500 μm, preferably in a range of from 20 μm to 200 μm, particularly preferably in a range of from 40 μm to 150 μm. Preferably at least 100, further preferably at least 100,000, particularly preferably at least 100,000,000, are combined to form a layer of the single crystal. Preferably at least 1,000, further preferably at least 1,000,000, particularly preferably at least 1,000,000,000, crystallites are combined to form the single crystal.

The method is preferably carried out in a hermetically sealed chamber. The chamber can be evacuated and/or be filled with inert gas. The material properties can thereby be controlled particularly well. Moreover, the component is protected from undesired oxidation.

The component can also be produced with several single crystals according to the invention. The component can, in addition to one or more single crystals, have polycrystalline, in particular fine crystalline, regions.

The component can be in particular a thermally and/or mechanically highly loaded component, preferably a turbine blade. The turbine blade can be provided for land- or air-based turbines, in particular gas turbines or water turbines. The turbine can be used in a stationary or mobile manner. Furthermore, the turbine blade can be used in drives, in particular in jet engines, or in generators.

The crystal orientation of the single crystals produced with the method according to the invention is advantageously optimized by adjustment of the extension direction, speed and/or temperature of the melted linear region. The crystal orientation, in particular the primary and/or the secondary crystal orientation, can preferably be adjusted very exactly by means of the method according to the invention. The quality in the production of the single crystals is thereby improved. The method according to the invention is particularly suitable for components for high-temperature applications, e.g. with nickel-based alloys, electrical and/or thermal applications, e.g. with pure copper or copper alloys, or functional applications, in particular with shape-memory alloys, e.g. nitinol.

Monocrystalline and polycrystalline regions can advantageously be combined very flexibly with each other in the component by means of the method according to the invention.

The mechanical properties of a component produced by means of the method according to the invention, in particular of a turbine blade produced by means of the method according to the invention, can advantageously be locally adapted. The local adaptation can be effected on the one hand by precisely adjusting the crystal orientation, in particular the primary and/or the secondary crystal orientation, of monocrystalline regions in the turbine blade. On the other hand, these monocrystalline regions in the turbine blade can be surrounded in a precisely defined manner by fine-crystalline regions. A failure of the material of the turbine blade is thereby advantageously prevented.

By means of the method according to the invention, monocrystalline components the crystal orientation of which is precisely adapted to the loading case can advantageously be produced. In particular, the crystal orientation can be adapted to the course of stress lines and/or force lines in the component. In addition, the crystal orientation itself can be continuously adapted to the local loads in the component.

Furthermore, the method according to the invention can also be used to repair and/or supplement monocrystalline components. For example, a broken-off tip of a monocrystalline component can be restored by means of the method according to the invention.

According to an advantageous embodiment of the invention, the linear region has a length along its extension direction and a width perpendicular thereto. The ratio of length and width is preferably at least 2:1, more preferably at least 5:1 and particularly preferably at least 20:1. By the provision of such a ratio of length and width of the linear region, a particularly pronounced anisotropy is advantageously generated in the mechanical stress field. This particularly pronounced anisotropy makes a particularly precise adjustment of the crystal orientation of the single crystal to be produced possible.

According to a further advantageous embodiment of the invention, the linear region has a width and a depth which are each perpendicular to its extension direction. The ratio of width and depth lies in a range of from 1:2 to 10:1, preferably in a range of from 2:1 to 4:1. Through the provision of such a ratio of width and depth of the linear region, a particularly high quality of the single crystals produced is advantageously achieved.

According to a further advantageous embodiment of the invention, the depth of the linear region is 50 μm to 1000 μm, preferably 150 μm to 500 μm. The depth of the linear region is preferably dimensioned such that the linear region not only extends inside the new layer, but at least partially penetrates into one or more of the layers produced directly beforehand.

The quality of the single crystals produced can thereby be further increased.

According to a further advantageous embodiment of the invention, the component is produced layer by layer by local melting of a powder layer of the metallic material and/or by local application of the metallic material. The component is thus preferably produced by means of additive manufacturing. The powder layer can be provided as a fill with the aid of a doctor blade. The local application of the metallic material can be effected for example by providing a wire or a powder according to the method of direct energy deposition. This method is also known by the abbreviation DED. In the process the wire and/or the powder are melted by a focused heat source, for example a laser, an electron beam or an electric arc. The heat source is preferably attached to a gantry system or a robot arm. This method is advantageous in particular in the repair of monocrystalline components.

According to a further advantageous embodiment of the invention, the metallic material in the linear region is melted by a laser and/or an electron beam.

During the construction of the new layer the metallic material is preferably heated in the entire new layer by the laser and/or the electron beam. For this, the laser and/or electron beam preferably periodically sweeps over the new layer. The laser and/or electron beam can sweep over the new layer several times in predefined time periods. In the linear region, the intensity or the dwell time of the laser and/or electron beam is preferably chosen such that a melting of the metallic material results.

The method is preferably carried out according to the known methods of Selective Laser Melting, which is also known by the term Laser Powder Bed Fusion and by the abbreviations SLM, LPBF, L-PBF or PBF-L, and/or of Selective Electron Beam Melting, which is also known by the term powder bed fusion electron beam and by the abbreviations SEBM or PBF-EB. In these methods, the component is constructed layer by layer in a powder bed.

For selective laser melting, the component is preferably constructed layer by layer by means of a powder bed in an installation space inside a process chamber. For this, powder layers of the metallic material are deposited with a doctor blade, heated with a laser and selectively melted. The metallic material can be heated so strongly by multiple scanning with the laser that a selective melting is effected. The installation space is preferably brought to a sufficiently high temperature by heating elements, with the result that the metallic material can be selectively melted by the laser. The temperature required for this can be provided in the installation space from the bottom, the side or from the top by heating elements. Heating from the top can alternatively or additionally be done by radiation, e.g. infrared radiation. The power of the laser preferably lies in a range of from 50 to 5,000 W. Selective laser melting is preferably carried out under the atmosphere of a protective gas. The protective gas preferably comprises argon, helium and/or nitrogen. Alternatively, selective laser melting can be carried out in a vacuum. The installation space inside the process chamber preferably has a construction plane as xy plane and a height in the z direction. The dimension of the installation space is preferably 100 to 500 mm in the construction plane and/or 100 to 1000 mm in the height. The laser is preferably controlled via actuator-controlled mirrors. The power introduced by the laser into the installation space and in particular into the linear region, into the heat-affected zone and/or into the new layer is preferably modulated by its scanning speed and/or intensity. In the case of pulsed lasers, the pulse frequency can furthermore be varied.

Selective electron beam melting is particularly preferred. The component is preferably constructed layer by layer by means of a powder bed in an installation space inside a vacuum chamber. For this, powder layers are deposited with a doctor blade, heated by multiple scanning with an electron beam and then selectively melted. The power of the electron beam preferably lies in a range of from 0.1 to 40 KW. The installation space inside the vacuum chamber preferably has a construction plane as xy plane and a height in the z direction. The dimension of the installation space is preferably 100 to 500 mm in the construction plane and/or 100 to 1000 mm in the height. The electron beam is preferably controlled by means of magnetic fields. The electron beam preferably reaches speeds of up to 10,000 m/s. The power introduced by the electron beam into the installation space and in particular into the linear region, into the heat-affected zone and/or into the new layer is preferably modulated by its scanning speed and/or intensity.

The flexibility of the electron beam advantageously allows a temperature field and a temperature-time curve to be precisely adjusted. The linear region can thereby be generated particularly easily and flexibly. In particular, particularly fine and/or thin structures can be generated for the linear region.

According to a further advantageous embodiment of the invention, the component and/or an installation space containing the component is additionally heated.

The component and/or the installation space can also be heated by the laser and/or the electron beam. The heating of the component and/or of the installation space can result indirectly from the heating of the new layer and/or of the linear region. Alternatively or additionally, the component and/or the installation space can be heated by external heating. The external heating can be realized by additional heating units, in particular one or more infrared heaters, one or more inductive heating units and/or one or more resistance heating units.

According to a further advantageous embodiment of the invention, the metallic material, the component and/or the installation space is heated to a temperature in the range of from 300° C. to 1200° C., preferably to a temperature in the range of from 700° ° C. to 1200° C., particularly preferably to a temperature in the range of from 900° ° C. to 1100° C. In particular if nickel-based alloys are used, temperatures in the range of from 900° C. to 1100° C. are preferred.

The level of the mechanical stresses is dependent on the choice of the metallic material and on the temperature of the metallic material and/or of the component.

The mechanical stresses are relieved by plastic expansion up to the yield point. The yield point itself depends on the temperature. The method is preferably adjusted such that in each layer anisotropic plastic expansions of from 0.02 to 3%, particularly preferably from 0.2 to 1%, are introduced in the material. The anisotropic plastic expansions advantageously lead little by little, by texture formation, to the formation of a single crystal.

For nickel-based alloys, the yield stresses lie between 1000 MPa and 5 MPa at typical working temperatures of from 700° C. to 1200° C. It is advantageous to plastically reduce the thermal shrinkage as completely as possible. For this, the temperature of the metallic material and/or of the component is preferably so high that the yield point of the metallic material is low compared with the thermomechanical stresses.

According to a further advantageous embodiment of the invention, the layered construction is effected along a construction direction. Layers with thicknesses in the range of between 10 μm and 500 μm, particularly preferably in the range of between 30 μm and 100 μm, are preferably generated.

According to a further advantageous embodiment of the invention, the metallic material is formed of a nickel-based alloy, nickel-titanium alloy and/or copper alloy.

According to a further advantageous embodiment of the invention, the linear region is subjected to a lateral movement perpendicular to its extension direction with a lateral speed vₗₐₜ while maintaining its extension direction. The lateral speed vₗₐₜ is preferably between 0.1 mm/s and 100 mm/s, particularly preferably between 0.5 and 10 mm/s.

The length of the linear region can vary during this movement. The length of the linear region is preferably varied depending on a geometry of the component to be produced.

The lateral speed can be at least intermittently constant. The lateral speed at the start of a new layer is preferably equal to zero, until the metallic material has melted in the linear region. When the new layer is traversed, the lateral speed is preferably increased to a constant value. Before the new layer is completed, the lateral speed can be lowered again and preferably reach zero, while the metallic material is allowed to solidify in the linear region.

In particular embodiments of the invention, a short-term complete solidification of the metallic material can be provided in the linear region during the construction of a new layer. After that, the metallic material can be melted again at the same location or at another location to create the linear region.

According to a further advantageous embodiment of the invention, a crystal orientation of the single crystal is adjusted in a defined manner by adjustment of extension direction and lateral movement of the linear region in successive layers.

The crystal orientation, in particular the primary and the secondary crystal orientation, is preferably adjusted in a defined manner. The crystal orientation can be adjusted such that it remains constant in the construction direction. In particular, the primary and the secondary crystal orientation can be adjusted such that they remain constant in the construction direction. Alternatively, the crystal orientation can be adjusted such that it changes in a defined manner in the construction direction. In particular, the primary and the secondary crystal orientation can be adjusted such that they change in a defined manner in the construction direction, e.g. rotate and/or tilt continuously. It is to be borne in mind here that the crystal orientation may change within the single crystal. As long as no high-angle grain boundaries occur, a single crystal or a “technical single crystal” is still referred to.

According to a further advantageous embodiment of the invention, the extension direction of the linear region in successive layers is the same or is rotated by an angle corresponding to a rotational symmetry of the crystal lattice. The extension direction of the linear region in successive layers in the case of a cubic crystal lattice is preferably the same or rotated by 90°.

The primary crystal orientation can be tilted little by little during the growth of the single crystal in the z direction, i.e. in the construction direction, by the extension direction of the linear region repeatedly remaining the same in successive layers.

The crystal orientation, in particular the primary and the secondary crystal orientation, can be kept constant in the z direction, i.e. in the construction direction or in the growth direction of the single crystal, by rotating the extension direction of the linear region in successive layers by for example 90° corresponding to the rotational symmetry of the crystal lattice.

According to a further advantageous embodiment of the invention, the direction of the lateral movement of the linear region in successive layers is the same or is rotated by an angle corresponding to a rotational symmetry of the crystal lattice. The direction of the lateral movement of the linear region in successive layers in the case of a cubic crystal lattice is preferably the same or rotated by 90°, 180° or 270°.

The primary crystal orientation is preferably tilted little by little during the growth of the single crystal in the z direction, i.e. in the construction direction, by the extension direction of the linear region and the direction of the lateral movement of the linear region repeatedly remaining the same in successive layers.

The primary crystal orientation can be tilted in the z direction continuously by 0.01° to 3° per layer, preferably by 0.1° to 2° per layer, particularly preferably by 0.5° to 1° per layer. Through repeated performance of the tilting in successive layers, a total tilt angle of up to 45° with respect to the z direction can preferably be achieved. In the case of a layer thickness of for example 50 μm and a tilt of 1° per layer, a total tilt angle of 45° can be achieved in the case of a growth of the single crystal by 2,250 μm in the z direction. Once a desired tilt angle has been achieved, a completely symmetrical melt strategy is preferably returned to, i.e. the primary and/or secondary crystal orientation is preferably kept constant, as described below.

The crystal orientation, in particular the primary and the secondary crystal orientation, is preferably kept constant in the z direction, i.e. in the construction direction or in the growth direction of the single crystal, by rotating the extension direction of the linear region and the direction of the lateral movement of the linear region in successive layers by an angle corresponding to a rotational symmetry of the crystal lattice. The extension direction of the linear region and the direction of the lateral movement of the linear region in successive layers in the case of a cubic crystal lattice are preferably rotated for this in each case by 90°. The direction of the lateral movement of the linear region is thus preferably rotated by 180° in the next but one layer, by 270° in the third next layer, by 360° in the fourth next layer, and so on.

This procedure is particularly advantageous in the case of cubic crystal systems. As a result, components with almost exact alignment of the direction in the z direction, for example with a maximum deviation of from 1 to 2°, advantageously form. This means a substantial improvement compared with conventional methods. In the case of casting methods, deviations of up to 15° have to be tolerated.

It is furthermore advantageous that a single crystal mosaicity dependent on the component size is not to be observed in the case of the method according to the invention. By single crystal mosaicity is meant that the dendrites inside the single crystal are not all aligned identically.

In the xy plane the alignment of the single crystal depends on the crystal-plastic properties of the material. For nickel-based alloys for example, the direction is rotated by 45° with respect to the extension direction of the linear region. The single crystal selection is effected in the region of a few millimeters.

According to a further advantageous embodiment of the invention, the extension direction and the direction of the lateral movement of the linear region in successive layers, in particular in directly successive layers, or in each case after a particular number of layers, are rotated by an equal angle value, preferably by 0.01° to 10° per layer, particularly preferably by 0.1° to 1° per layer.

The crystal orientation, in particular the secondary crystal orientation, with respect to the xy plane, i.e. the construction plane, of the single crystal can thereby be rotated, preferably continuously by 0.01° to 10° per layer, preferably by 0.1° to 1° per layer, particularly preferably by 0.3° to 0.7° per layer. The rotation of the single crystal is effected in a stress-induced manner.

The primary crystal orientation can additionally be kept constant by rotating the extension direction of the linear region and the direction of the lateral movement of the linear region in successive layers additionally by an angle corresponding to a rotational symmetry of the crystal lattice. The extension direction of the linear region and the direction of the lateral movement of the linear region in successive layers in the case of a cubic crystal lattice are preferably rotated for this additionally in each case by 90°. The extension direction and the direction of the lateral movement of the linear region in successive layers are thus preferably rotated by 90°+0.01° to 90°+10° per layer, particularly preferably by 90°+0.1° to 90°+1° per layer.

According to a further advantageous embodiment of the invention, the extension direction of the linear region and/or the lateral movement of the linear region is varied during the construction of the new layer. In relation to the lateral movement of the linear region, the direction of the lateral movement and/or the value of the lateral speed can be varied.

Alternatively or additionally, the extension direction of the linear region and/or the lateral movement of the linear region in the construction direction can be varied. In relation to the lateral movement of the linear region, the direction of the lateral movement and/or the value of the lateral speed can also be varied. The variation can be provided in the construction direction in a specific sequence of successive layers. For example, the variation can be provided in directly successive layers or in each case after a particular number of layers.

According to a further advantageous embodiment of the invention, a linear region is melted only in subregions of the component.

According to a further advantageous embodiment of the invention, monocrystalline and polycrystalline, in particular fine-crystalline, regions are produced in the component. It is possible for monocrystalline and polycrystalline, in particular fine-crystalline, regions to be produced in an alternating manner. Monocrystalline and polycrystalline, in particular fine-crystalline, regions are preferably produced lying next to each other. For example, a monocrystalline region can be produced surrounded by a fine-crystalline shell. The monocrystalline regions are preferably formed in each case by a single crystal according to the invention, i.e. by a single crystal produced according to the method according to the invention.

For example, a turbine blade can be produced from a single crystal surrounded by a fine-crystalline shell according to the method according to the invention. Such a turbine blade is advantageously characterized by locally adapted mechanical properties. This can be advantageous e.g. for the fatigue behavior.

According to a further advantageous embodiment of the invention, a continuous change in the crystal orientation is produced in the component, preferably a continuous rotation about the construction direction and/or a continuous tilting with respect to the construction direction, preferably by 0.01° to 10° per layer, particularly preferably by 0.1° to 1° per layer.

As already explained above, the tilting with respect to the construction direction relates to the primary crystal orientation and the rotation about the construction direction relates to the secondary crystal orientation.

For metals and alloys which do not solidify in the cubic crystal system, but e.g. form hexagonal crystals, the above-named construction strategies have to be adapted to the symmetry of the lattice in order to generate analogous effects.

In accordance with the invention, a component comprising a single crystal or several single crystals with exactly adjusted primary and/or secondary crystal orientation is furthermore claimed. The component is preferably produced by means of the method according to the invention. The primary and/or the secondary crystal orientation can be adjusted such that they are constant over the entire single crystal or over the entire component or in portions. Furthermore, the primary and/or the secondary crystal orientation can be adjusted such that they change over the entire single crystal or over the entire component or in portions, in particular change continuously.

The component is preferably a turbine blade. The turbine blade is preferably installed in a gas turbine. The gas turbine is preferably land- or air-based.

A component according to the invention, in particular a turbine blade according to the invention, advantageously has locally adapted mechanical properties.

The invention will now be explained in more detail with reference to embodiment examples. There are shown in

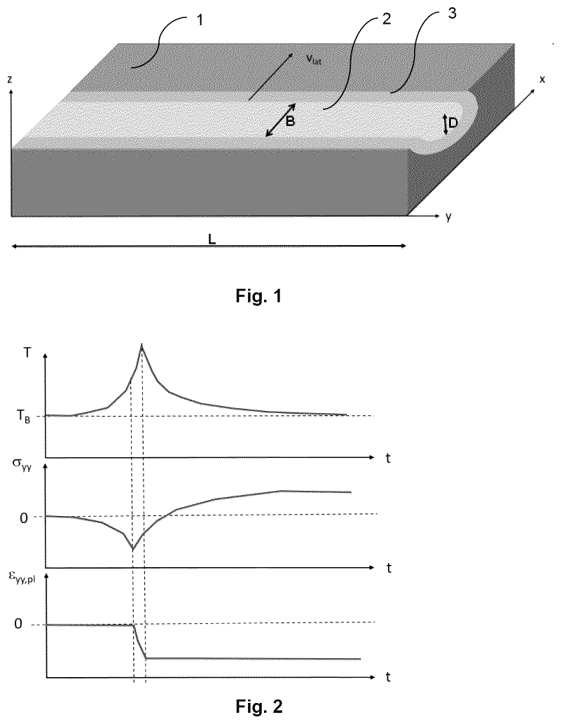

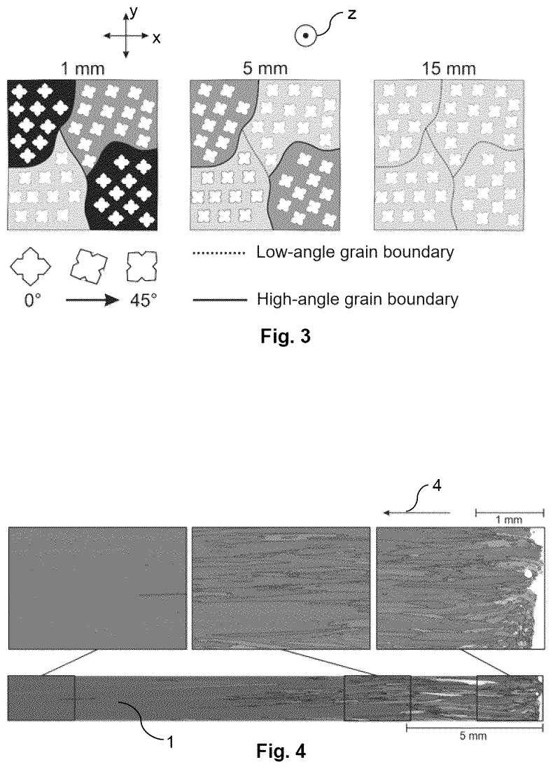

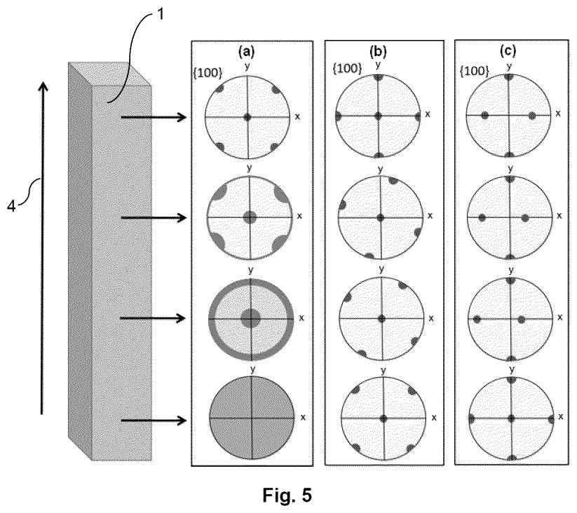

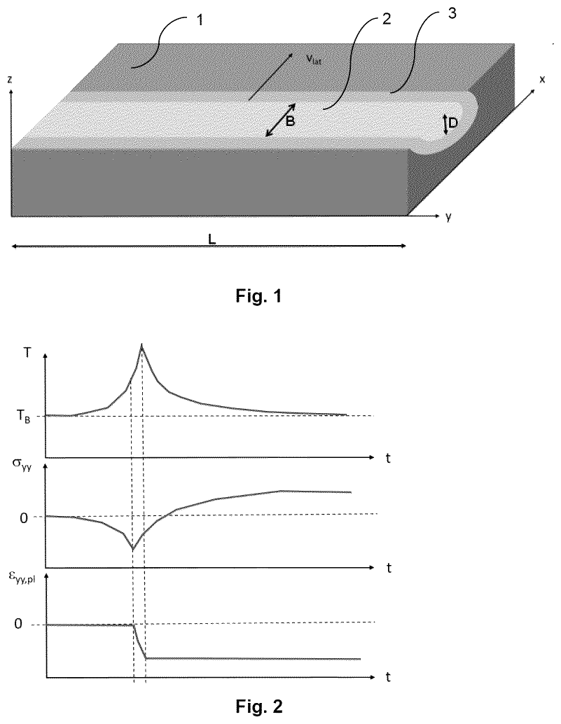

FIG. 1 a schematic representation of a component in production with a linear region,

FIG. 2 a schematic drawing of time curves of temperature, stress and plastic expansion in a heat-affected zone,

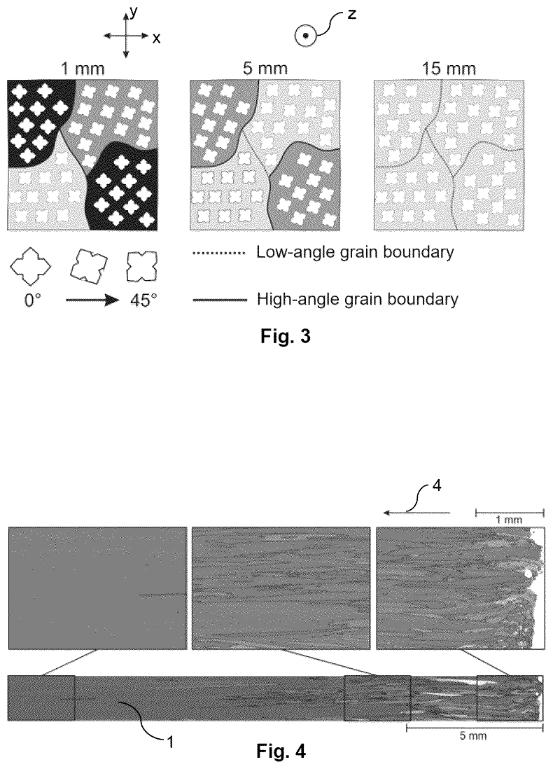

FIG. 3 a schematic representation of a formation of a monocrystalline component,

FIG. 4 an experimental example of a formation of a monocrystalline component,

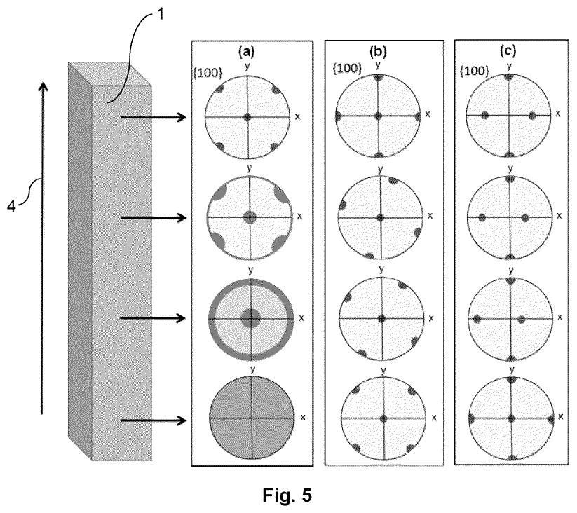

FIG. 5 a schematic drawing with pole figures to describe the formation of a monocrystalline component as well as the rotation and the tilting of the crystal orientation.

FIG. 1 shows a schematic representation of a component 1 in production with a linear region 2. The component 1 is constructed layer by layer from a metallic material in an installation space inside a vacuum chamber. In order to construct a new layer, powder layers of the metallic material are preferably deposited as a powder bed with a doctor blade, heated by multiple scanning with an electron beam and selectively melted in the linear region 2. The thickness of the new layer is for example 50 μm. The power of the electron beam is for example 1 kW. The installation space has an xy plane as construction plane and a z direction as construction direction. The dimension of the installation space is for example 300 mm in the construction plane and 300 mm in the construction direction.

The metallic material is melted in the linear region 2 by selective electron beam melting. The linear region 2 has a length L along its extension direction and a width B and a depth D which are each perpendicular to its extension direction. The depth D of the linear region is for example 500 μm. The linear region 2 thus also penetrates into the ten layers produced directly before the new layer. The width B of the linear region is for example 1.5 mm. The length L of the linear region is for example 15 mm. The linear region 2 is surrounded by a heat-affected zone 3. The metallic material in the heat-affected zone 3 is not melted, more precisely is in part not yet melted, in part no longer melted. In the heat-affected zone 3, a temperature field generated by the electron beam acts in particular on the already solidified metallic material in layers produced directly before the new layer.

The linear region 2 is moved with a lateral speed vₗₐₜ perpendicular to its extension direction. The lateral speed vₗₐₜ is for example 5 mm/s.

A plastic deformation of the metallic material in the course of thermally induced mechanical stresses is caused by the melting and the subsequent solidification of the metallic material. The mechanical stresses are generated in a targeted manner by adjustment of the extension direction, speed and temperature of the linear region. The mechanical stresses exceed the yield point of the metallic material in particular in the linear region 2 and/or in the heat-affected zone 3. The mechanical stresses have a preferred direction because of the linear design of the linear region. The mechanical stress field is thus anisotropic. This anisotropy leads to the generation of a single crystal. The crystal orientation, in particular the primary and secondary crystal orientation, can be precisely adjusted by the mechanical stress field generated in a targeted manner by adjustment of extension direction, speed and temperature of the linear region.

FIG. 2 shows, in a schematic drawing, the temperature T, the mechanical stress in the y direction σ_{yy} and the plastic expansion in the y direction ε_{yy} in each case as a function of time t in the heat-affected zone 3. The construction temperature is labeled T_{B}. In the construction plane, i.e. in the xy plane, the symmetry is broken with respect to the mechanical stress and the plastic expansion. This symmetry breaking, coupled with the property of crystals to align in particular directions due to plastic deformation, which is called texture formation, ultimately leads to the controlled alignment of each individual columnar crystal and finally to the generation of the single crystal.

FIG. 3 shows a schematic representation of a formation of a monocrystalline component. In it, the alignment of individual crystallites at different construction heights during the construction of a component is visualized. The construction direction 4 is perpendicular to the paper plane, thus runs in the z direction. The extension direction of the linear region 2 lies in the paper plane and, alternating from layer to layer, is parallel to the x axis in a first layer, parallel to the y axis in a second layer, and so on. The movement direction of the linear region 2 moved with the lateral speed vₗₐₜ perpendicular to its extension direction changes by 90° clockwise from layer to layer. The primary crystal orientation is already precisely adjusted after a few 100 μm construction height: the individual crystallites are in each case aligned in the z direction, i.e. in the direction. At 1 mm the secondary crystal orientation is still isotropic. With increasing construction height, each individual crystallite is rotated little by little to an angular position with respect to the x axis of 45°, i.e. the secondary crystal orientation is also precisely adjusted. Between a construction height of 5 mm and 15 mm the high-angle grain boundaries (represented by continuous lines) disappear. Only low-angle grain boundaries (represented by dotted lines) persist. The crystallites are therefore finally melted completely to form a single crystal at a construction height of 15 mm.

FIG. 4 shows an experimental example of a formation of a monocrystalline component 1. The specific example involves a nickel-based single crystal alloy of the CMSX-4 type. The production is effected by selective electron beam melting. A section of the rod-shaped component 1 is depicted in the lower part of FIG. 4. The construction direction 4 represented by an arrow goes from right to left. The gray tones show different crystal orientations. High-angle grain boundaries are characterized by black lines. In the upper part of FIG. 4, by way of example, three sections of the rod-shaped component are represented enlarged. The enlarged section shown on the right relates to the first 2 mm in the construction direction 4. In it, many different crystal orientations with high-angle grain boundaries lying in between are still to be observed. The enlarged section shown in the middle relates to a construction height of from approximately 5 to 7 mm in the construction direction 4. Here, the crystal orientation has already converged in larger regions. The high-angle grain boundaries disintegrate more and more with advancing construction height. The enlarged section shown on the left relates to a construction height of from approximately 22 to 24 mm in the construction direction 4. Here, the crystal orientation has largely converged. The high-angle grain boundaries are disintegrated for the most part. The disappearance of the high-angle grain boundaries shows the melting to form the single crystal.

FIG. 5 shows a schematic drawing with pole figures to describe the formation (a) of a monocrystalline component 1 as well as the rotation (b) of the secondary crystal orientation and the tilting (c) of the primary crystal orientation of the monocrystalline component 1. A rod-shaped component 1 is shown schematically in a left-hand column. The construction direction 4 runs from the bottom to the top in the z direction, represented by a vertical arrow in the figure. One pole figure is represented in each case for four different construction heights. The four different construction heights are marked in each case by a horizontal arrow. The single crystal selection is represented in the next column (a) starting from an isotropic distribution in the bottom pole figure to a development of precisely defined positions in the top pole figure. A monocrystalline state is already precisely adjusted in the top pole figure of column (a). Starting from this monocrystalline state the secondary crystal orientation can be changed in a targeted manner. The crystal lattice can thus be rotated in the xy plane. This is visualized in column (b) with reference to four further pole figures. The bottom pole figure corresponds to the top pole figure of column (a). To rotate the crystal lattice, the scanning direction of the electron beam and thus the extension direction of the linear region 2 is rotated in the xy plane by for example 0.5°+90° per layer. Starting from the state in the bottom pole figure, the secondary crystal orientation in column (b) is rotated successively by 45° up to the top pole figure. After that, the primary crystal orientation is changed in a targeted manner in column (c). The single crystal is tilted with respect to the z direction. This is visualized in column (c) with reference to four further pole figures. The bottom pole figure there corresponds to the top pole figure of column (b). The tilting of the single crystal is effected by symmetry breaking. A symmetry breaking can be achieved by the extension direction of the linear region 2 and its movement direction remaining the same in successive layers.

Even if the portions in which the component 1 still does not have a monocrystalline state in an initial phase of the production method are nevertheless already called component 1 here, it is self-evident that preferably only the portions after single crystal selection has been effected finally form the component 1. For this, the portions from the initial phase of the production method can be detached from the component 1.

### LIST OF REFERENCE NUMBERS

1 component
2 linear region
3 heat-affected zone
4 construction direction
L length
B width
D depth
σ_{yy} mechanical stress in the y direction
ε_{yy} plastic expansion in the y direction
T temperature
T_{B} construction temperature

1. A method for producing a component (1) by means of layered construction, comprising combining a plurality of crystallites of a metallic material to form a single crystal, wherein the single crystal is formed by thermomechanically activated successive anisotropic plastic deformation, wherein the metallic material is heated during the construction of a new layer, with the result that the metallic material is melted in a linear region,
wherein mechanical stresses occur during melting and subsequent cooling, in particular solidification, of the metallic material, wherein the plastic deformation of the metallic material is caused by these mechanical stresses,
wherein the mechanical stresses have a preferred direction because of the linear design of the melted linear region, whereby the anisotropic plastic deformation results, and
wherein the new layer is gradually constructed by being traversed by the melted linear region, wherein the component is constructed layer by layer in a construction direction,
wherein the linear region has a length (L) along its extension direction and a width (B) and a depth (D) which are both perpendicular to the extension direction of the linear region, wherein the ratio of length (L) and width (B) is at least 5:1, wherein the ratio of width (B) and depth (D) lies in a range of from 1:2 to 10:1, wherein the linear region is moved in order to construct the new layer, and
wherein the linear region is subjected to a lateral movement perpendicular to its extension direction with a lateral speed vₗₐₜ while maintaining its extension direction.

2. The method according to claim 1, wherein the ratio of length (L) and width (B) is at least 20:1.

3. The method according to claim 1, wherein the ratio of width (B) and depth (D) lies in a range of from 2:1 to 4:1.

4. The method according to claim 1, wherein the depth (D) of the linear region is in the range from 50 μm to 1000 μm.

5. The method according to claim 1, wherein the component is produced layer by layer by at least one of local melting of a powder layer of the metallic material or local application of the metallic material.

6. The method according to claim 1, wherein the metallic material in the linear region is melted by at least one of a laser or an electron beam.

7. The method according to claim 1, wherein the component or an installation space containing the component is additionally heated.

8. The method according to claim 1, wherein at least one of the metallic material, the component or the installation space is heated to a temperature (T) in the range of from 300° ° C. to 1200° C.

9. The method according to claim 1, wherein the layered construction is effected along a construction direction (4) and layers with thicknesses in the range of between 10 μm and 500 μm are generated.

10. The method according to claim 1, wherein the metallic material is formed of at least one of a nickel-based alloy, a nickel-titanium alloy or a copper alloy.

11. The method according to claim 1, wherein the lateral speed vₗₐₜ is between 0.1 mm/s and 100 mm/s.

12. The method according to claim 11, wherein a crystal orientation of the single crystal is adjusted in a defined manner by adjustment of extension direction and lateral movement of the linear region in successive layers.

13. The method according to claim 1, wherein the extension direction of the linear region in successive layers is the same or is rotated by an angle corresponding to a rotational symmetry of the crystal lattice.

14. The method according to claim 1, wherein the direction of the lateral movement of the linear region in successive layers is the same or is rotated by an angle corresponding to a rotational symmetry of the crystal lattice.

15. The method according to claim 1, wherein the extension direction and the direction of the lateral movement of the linear region in successive layers, or in each case after a particular number of layers, are rotated by an equal angle value.

16. The method according to claim 1, further comprising at least one of the following:
varying the extension direction of the linear region during the construction of the new layer,
varying the lateral movement of the linear region during the construction of the new layer,
varying
the extension direction of the linear region in the construction direction, or
varying the lateral movement of the linear region in the construction direction.

17. The method according to claim 1, wherein a linear region is melted only in subregions of the component.

18. The method according to claim 1, wherein monocrystalline and polycrystalline regions are produced in the component.

19. The method according to claim 1, wherein a continuous change in the crystal orientation is produced in the component.

20. A component comprising a single crystal with exactly adjusted primary and secondary crystal orientation, produced by a means of layered construction, comprising combining a plurality of crystallites of a metallic material to form a single crystal, wherein the single crystal is formed by thermomechanically activated successive anisotropic plastic deformation, wherein the metallic material is heated during the construction of a new layer, with the result that the metallic material is melted in a linear region,
wherein mechanical stresses occur during melting and subsequent cooling, in particular solidification, of the metallic material, wherein the plastic deformation of the metallic material is caused by these mechanical stresses,
wherein the mechanical stresses have a preferred direction because of the linear design of the melted linear region, whereby the anisotropic plastic deformation results, and
wherein the new layer is gradually constructed by being traversed by the melted linear region, wherein the component is constructed layer by layer in a construction direction,
wherein the linear region has a length (L) along its extension direction and a width (B) and a depth (D) which are both perpendicular to the extension direction of the linear region, wherein the ratio of length (L) and width (B) is at least 5:1, wherein the ratio of width (B) and depth (D) lies in a range of from 1:2 to 10:1, wherein the linear region is moved in order to construct the new layer, and wherein the linear region is subjected to a lateral movement perpendicular to its extension direction with a lateral speed vₗₐₜ while maintaining its extension direction.
